(19) United States
(12) Patent Application Publication
(10) Pub. No.: US 2011/0109602 A1
(43) Pub. Date: May 12, 2011

(54) FAULT DETECTION APPARATUS FOR ALPHANUMERIC DISPLAY SYSTEM AND METHOD OF DETECTING A FAULT

(75) Inventor: Kurt Neugebauer, Vaterstetten (DE)

(73) Assignee: Freescale Semiconductor, Inc., Austin, TX (US)

(21) Appl. No.: 13/003,948

(22) PCT Filed: Jul. 16, 2008
(86) PCT No.: PCT/IB08/52858

§ 371 Date: Jan. 13, 2011

(51) Int. Cl. H03M 13/09; G06F 3/038; G06F 11/10

(52) U.S. Cl. 345/204; 714/819; 714/E11.032

(57) ABSTRACT

A fault detection apparatus comprises a signal translation stage having an input arranged to receive an input waveform derived from a signal for a capacitive load. The signal translation stage is arranged to generate a translated output signal representative of at least an aspect of the input waveform. The apparatus also comprises a detection stage arranged to receive the translated output signal from the signal translation stage and analyse a first part and a second part of the translated output signal respectively corresponding to a first step function and a second step function, the first and second step functions being opposite in direction of transition. The analysis performed by the detection stage is a comparison of the first and second parts of the translated output signal respectively with an expected first part and an expected second part of the translated output signal.

### FIELD OF THE INVENTION

This invention relates to a fault detection apparatus of the type that, for example, is coupled to a capacitive load, such as a display segment, for detection of a fault with respect to the capacitive load. This invention also relates to a display system of the type that, for example, comprises a display segment and a fault detection apparatus coupled thereto. This invention further relates to a method of detecting a fault of the type that, for example, is used in respect of a capacitive load, such as a display segment, for detection of a fault with respect of the capacitive load.

### BACKGROUND OF THE INVENTION

In the field of alphanumeric displays, it is known to use Liquid Crystal Display (LCD) devices in the form of segmented display modules in order to present alphanumeric information. One example type of segmented display module is a GD-3980P display module available from S-Tek Displays Cleveland, Ohio. The display module comprises an arrangement of 8 Twisted Nematic (TN) LCD segments in a formation that resembles a number “8”. As will be appreciated, each LCD segment comprises a pair of electrodes either side of a cell of liquid crystal material. Of course, this is a simplified description of the structure of the segments. However, for the sake of appreciating technical problems associated with the segments the above simplification is adequate.

In order to power selectively each element of the segmented display module and hence drive the segmented display module, the electrodes of each cell of the segmented display module are coupled to respective driver outputs of a display driver: an integrated circuit that is used to control or drive the elements of the segmented display module. To reduce the number of driver outputs and hence the hardware complexity of the display driver, a driving configuration comprising one or more so-called “back plane” electrodes and a number of so-called “front plane” electrodes can be employed. Typically, the display driver comprises a greater number of front plane outputs than back plane outputs.

To drive the segmented display module, one known method of driving is known as “static” driving. Static driving of the segmented display module is typically used where a single back plane electrode is shared by all segments of the segmented display module, and each segment comprises a dedicated front plane electrode coupled to a respective front plane output of the display driver, Alternating Current (AC) waveforms being applied across the black plane electrode and the front plane electrodes.

However, by careful organisation of the back plane electrodes and the front plane electrodes and generation of driving waveforms therefor, the back plane electrodes can be coupled to more than one segment of the segmented display module and the front plane electrodes can similarly be coupled to more than one segment of the segmented display module whilst maintaining the ability to drive selectively one or more of the segments of the segmented display module using a reduced number of driving outputs. In this respect, an alternative driving technique known as dynamic driving is used in such instances where more than one backplane output of the display driver is used, each backplane output being shared by a number of the segments of the segmented display module. The potential differences generated by the driver circuit between the back plane and front plane outputs thereof are time division multiplexed so that one or more elements of the segmented display module can appear independently selected.

Like many electronic devices, the segmented display module and/or the display driver are susceptible to errors and/or faults, either during manufacture or during a working lifetime. One known type of fault is visually observable as incorrect activation of one or more segments of the segmented display module. Such faults can be observed as dimmed or unexpectedly illuminated segments caused by, for example, defective input/output pins of the driver circuit and/or incorrect driving of the segments, for example due to oxidation of metallic connectors. Leakage currents in segments or short circuits caused elsewhere can also cause one or more segments to be dimmed or illuminated unexpectedly. Furthermore, segments can fail to illuminate when open circuits occur, for example in connections between the display driver and one or more segments of the segmented display module.

Such faults are particularly undesirable in certain fields of application. For example, in the field of electronic medical instruments, an incorrectly displayed measurement, for example, an incorrectly displayed blood-glucose measurement can cause a patient to self-administer or a medical professional to administer, an incorrect treatment. The undesirability of faulty segments of segmented display modules is not limited to use of such segmented display modules in medical applications and similar considerations exist in other fields, for example in nuclear energy-related applications, which are not necessary related to radiography.

U.S. Pat. No. 6,927,749 relates to an LCD device having a plurality of segments, and an inverse segment that covers, at least in part, a display area that is not covered by remaining segments. The inverse segment can be used to allow detection of faulty segments by visual inspection. However, it should be appreciated that not all types of fault are visually detectable and so the solution proposed in U.S. Pat. No. 6,927,749 is only a partial solution. Additionally, complexity of the LCD device has to be increased in order to accommodate the proposed solution and an additional driver output is required.

EP-B1-0 031 015 relates to symbol segments of a passive liquid crystal cell. Each cell is connected to two leads. A first lead of each segment is connected to a control unit via a control bus provided, the control unit being used to operate the segment. A second lead of each segment is connected to a monitor unit via another bus, the monitor unit being used to compare potentials at each segment with a corresponding potential at the control unit. The comparison is used to verify correct operation of connections between the control unit and each cell segment. However, not all faults and errors that occur are attributable to faulty connections between a display driver and a segmented display module. Additionally, crude comparison of potentials does not identify errors or faults caused by more subtle errors in a driving waveform.

### SUMMARY OF THE INVENTION

The present invention provides a fault detection apparatus as described in the accompanying claims. The present invention also provides a display system as described in the accompanying claims. The present invention further provides a method of detecting a fault for a capacitive load as described in the accompanying claims.

Specific embodiments of the invention are set forth in the dependent claims.

These and other aspects of the invention will be apparent from and elucidated with reference to the embodiments described hereinafter.

### BRIEF DESCRIPTION OF THE DRAWINGS

Further details, aspects and embodiments of the invention will be described, by way of example only, with reference to the drawings. Elements in the figures are illustrated for simplicity and clarity and have not necessarily been drawn to scale.

FIG. 1 is a schematic diagram of an electronic medical apparatus using a display system;

FIG. 2 is a schematic diagram of the display system of FIG. 1 comprising a fault detection apparatus constituting an embodiment of the invention;

FIG. 3 is a schematic diagram of the display system of FIG. 2 in greater detail;

FIG. 4 is a flow diagram of a method of fault detection constituting another embodiment of the invention; and

FIG. 5 is a schematic diagram of a waveform and associated bit patterns.

### DETAILED DESCRIPTION OF THE PREFERRED EMBODIMENTS

Because the examples implementing the present invention may be, for the most part, composed of electronic components and circuits known to those skilled in the art, circuit details will not be explained in any greater extent than that considered necessary for the understanding and appreciation of the underlying concepts of the present invention and in order not to obfuscate or distract from the teachings of the present invention.

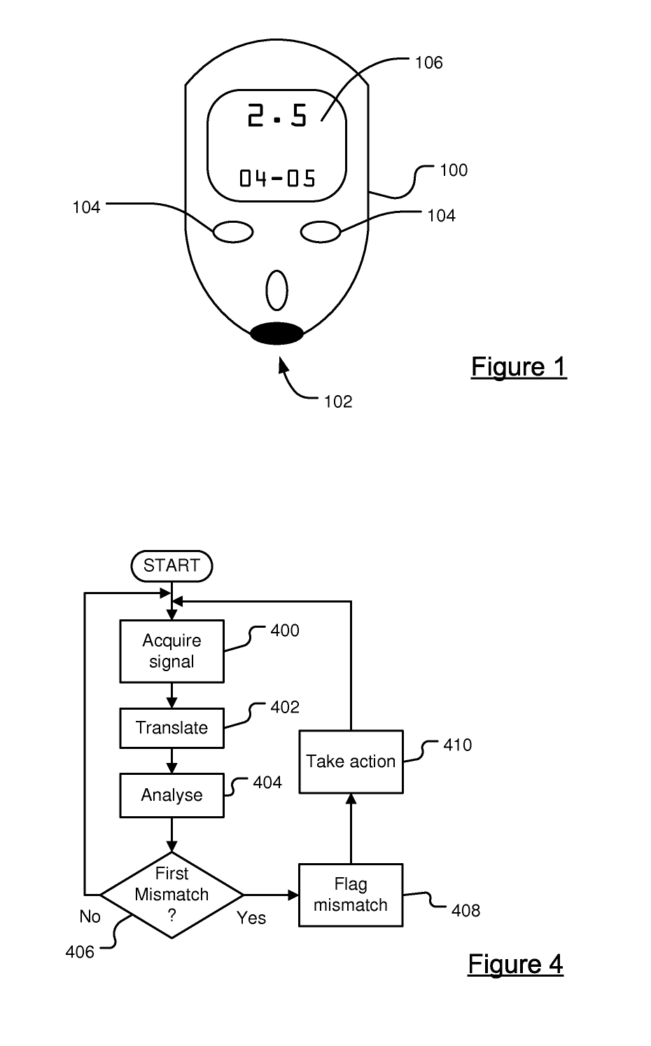

Referring to FIG. 1, an electronic apparatus, for example a glycometer 100 comprises an input port 102 for receiving a sample, control buttons 104 and a display 106. The glycometer 100 also comprises other hardware (not shown) in order to process a blood sample in order to provide a blood-glucose measurement for a patient via the display 106. Of course, the glycometer 100 is being described purely for exemplary purposes in order to illustrate use of a fault detection apparatus (not shown in FIG. 1) with the display device 106 and the skilled person should appreciate that embodiments described herein are not limited to use in relation to glycometers and other applications for the embodiments described herein are contemplated, for example in relation to radioactivity measurement.

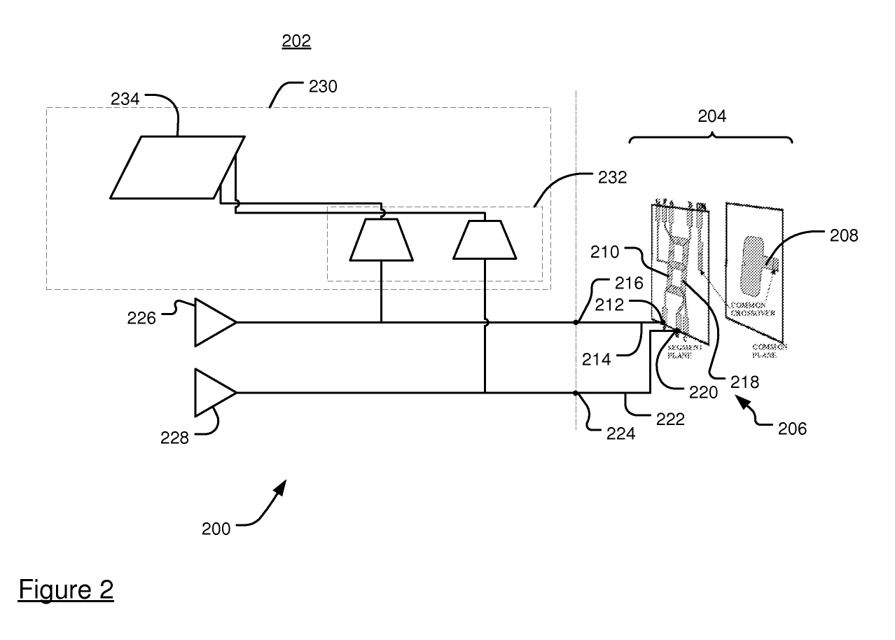

Turning to FIG. 2, a display system 200 comprises a semiconductor device, for example a microcontroller 202 coupled to a display 204 by circuit connections, the circuit connections being tracks of a Printed Circuit Board (PCB) (not shown) or any other suitable conductors. In this example, the display 204 is a segmented display module 206 comprising 7 segments arranged as a figure of ‘8’. The segmented display module 206 is an LCD module that comprises a plurality of front plane connections respectively coupled to each segment of the segmented display module 206 as will be described in further detail below.

The segmented display module 206 comprises a back plane electrode 208 coupled (not shown) to a back plane driver output (not shown) of the microcontroller 202. The segmented display module 206 also comprises a first segment 210 having an electrode thereof coupled to a first front plane connection port 212. The first front plane connection port 212 is coupled by a first circuit connection 214, for example a PCB track, to a first Input/Output (I/O) port 216 of the microcontroller 202. A second segment 218 has an electrode thereof coupled to a second front plane connection port 220. The second front plane connection port 220 is coupled by a second circuit connection 222, for example another PCB track, to a second I/O port 224 of the microcontroller 202. As will be appreciated, in this example, the segmented display module 206 comprises six other segments, which will not be described herein for the sake of conciseness and clarity of description. However, for the avoidance of doubt, the skilled person should appreciate that the embodiments described herein can be used in relation to some or all of the six other segments.

At the microcontroller 202, the first I/O port 216 is coupled to a first segment driver 226 and the second I/O port 224 is coupled to a second segment driver 228, the first and second segment drivers 226, 228 being part of a display driver circuit. However, the skilled person should appreciate that, for the purpose of testing the segmented display module 206, one or more dedicated test driver circuits can be employed. Use of the one or more dedicated driver circuits can be beneficial where a slower clock signal, than that used when driving the segmented display module 206 during normal operation, is required in order to obtain an increased number of sample points. One example of a suitable dedicated test driver circuit is a pull-up/pull-down driver circuit. In this respect, a pull-up driver can be used as follows. The first segment 210 of the segmented display module 206 is disabled. Then the pull-up driver activated for the first segment 210, followed by measurement of a transition caused by the pull-up driver in the manner described above. This technique can be employed for other segments of the segmented display module 206.

In order to detect a fault condition in relation to the display system 200, the display system 200 comprises a fault detection apparatus 230. The fault condition can arise as a result of any number of causes, for example faulty driving software, faulty physical connections and/or faulty segments of the segmented display module 206. In this example, the fault detection apparatus 230 comprises a signal translation stage 232 operably coupled to a detection stage 234.

It should be appreciated that the respective functionalities of the signal translation stage 232 and the detection stage 234 are not limited to the arrangement described above and, in some embodiments, the order in which the functionalities are performed can be varied and/or the functionalities performed in a single functional block.

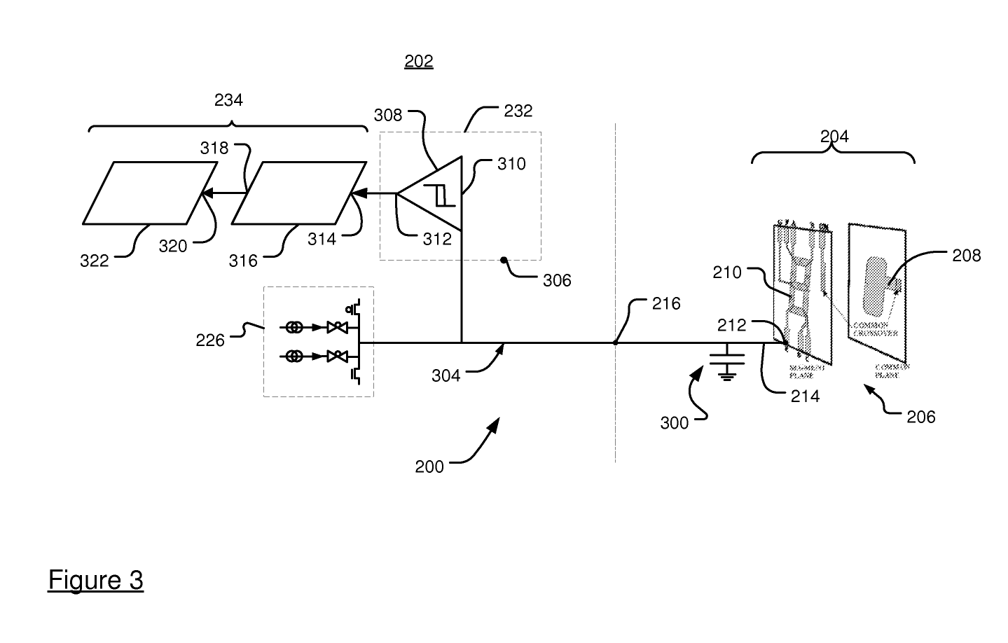

Referring to FIG. 3, further structural details of the display system 200 will now be described in the context of the first segment 210 and the connection to the microcontroller 202. In this respect, the first segment 210 can be modelled as a capacitive load 300. In this example, within the microcontroller 202, which is an Integrated Circuit (IC), a tap 304 is provided to couple the fault detection apparatus 230 to the connection between the first segment driver 226 and the first segment 210. It should therefore be appreciated that the term “tap” is being used to refer to any suitable coupling to the connection between the first segment driver 226 and the first segment 210 in order to obtain a copy of any signal communicated between the first segment driver 226 and the first segment 210.

The tap 304 is coupled to an input 306 of the signal translation stage 232. In this example, the signal translation stage 232 comprises a multi-state transformer circuit having multiple decision thresholds for generating an output having one of a number of, for example three, states based upon a signal level of an input. Furthermore, one or more of the thresholds can be set so that output logic states generated are optimised for post-processing. In this example, a Schmitt Trigger arrangement 308, such as a pair of coupled Schmitt Triggers, is employed and the tap 304 is coupled to an input 310 of the multi-state transformer 308, an output 312 of the multi-state transformer 308 being coupled to an input 314 of the detection stage 234. The detection stage 234, in this example, comprises a waveform post-processor module 316 providing the input 314 of the detection stage 234. An output 318 of the waveform post-processor module 316 is coupled to an input 320 of a control and data comparison module 322. In this example, the waveform post-processor module 316 is implemented in software, although the skilled person should appreciate that the waveform post-processor module 316 can be implemented in hardware using a Register Transfer Language (RTL) to design the necessary integrated circuit. Alternatively, a Field Programmable Gate Array (FPGA) can be employed. The control and data comparison module 322 is, in this example, implemented in software.

Although use of a Schmitt trigger is described herein to provide conversion from the analogue domain to the digital domain, the skilled person should appreciate that other hardware can be employed, for example, an Analogue-to-Digital Converter (ADC).

In operation (FIG. 4), the first segment driver 226 generates a driving signal constituting a waveform that drives the first segment 210. The translation stage 232 then obtains (Step 400) a copy of the waveform by tapping the waveform from the first circuit connection 214. The copy of the waveform can be used at start-up of the electronic apparatus 100 in order to identify a fault condition in relation to the first segment 210, although the skilled person will appreciate that the detection of the fault can take place at other times, for example between intervals of use or, in some embodiments, during normal operation.

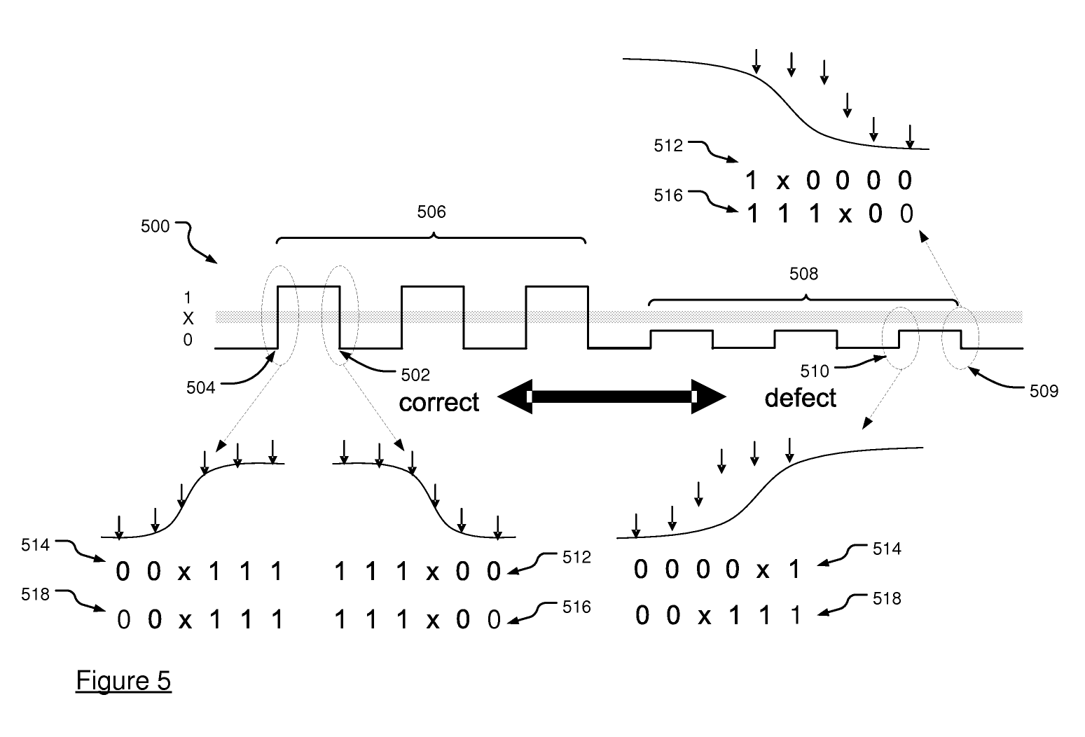

Referring to FIG. 5, as will be appreciated by the skilled person, the waveform 500 generated by the first segment driver 226 comprises cyclic step signals, each transition from a logic LOW (0) to a logic HIGH (1) constituting a step function and, likewise, each transition from a logic HIGH (1) to a logic LOW (0) also constituting a step function in an opposite direction. Consequently, the waveform comprises a first step function 502 transitioning from a logic HIGH to a logic LOW and a second step function 504 transitioning from a logic LOW to a logic HIGH, the second step function 504 following the first step function 502. Of course, the above description of the first and second step functions 502, 504 is exemplary and other observations of a waveform for driving a display segment can be interpreted as comprising the first step function 502 following the second step function 504. Furthermore, the step functions 502, 504 can have varying slew rates and amplitudes. Indeed, the step functions can transition with varying degrees of competence depending upon, for example, presence of the fault condition mentioned above. In the present example, the waveform 500 comprises a first number of transitions during a first time period 506 that are correct and as expected for driving the first segment 210. However, and in order to illustrate operation of the fault detection apparatus 100, the waveform 500 also comprises a second number of transitions during a second time period 508 that are associated with faulty driving and/or operation of the first segment 210.

As the copy of the waveform 500 is received, the signal translation stage 232 converts or translates (Step 402) the copy of the waveform from the analogue domain to the digital domain. Consequently, a detected bit pattern, constituting a translated output signal representative of at least on aspect of the waveform 500, is generated having a first part 512 in respect of the first step function 502 and a second part 514 in respect of the second step function 504. In this example, the signal translation module 232 is capable of generating one of three states in response to a signal level of the waveform 500 at a given instance in time. In this respect, the bit generated can be a logic 1, a logic 0 or an indeterminate state (“X”), for example a logic level that corresponds to any state possible. The skilled person should appreciate that when converting a signal from the analogue domain to the digital domain, the amplitude of the analogue signal is sometimes above a first threshold in which case the analogue signal at the given instant in time is classed as a logic 1 by the signal translation module 232. If the amplitude of the analogue signal is below a second threshold level, then the analogue signal at the given instant in time is classed as a logic 0, whereas if the signal level of the analogue signal at the given instant in time is between the first and second thresholds, then the analogue signal at the given instant in time is classed as corresponding to an indeterminate state, X.

The waveform post-processor 316 then analyses (Step 404) the detected bit pattern, firstly to identify the first part of the detected bit pattern corresponding to the first step function 502 and communicates the identified bits on to the control and data comparison module 322. The waveform post-processor 316 then identifies the second part 514 of the detected bit pattern corresponding to the second step function 504 and communicates the identified bits on to the control and data comparison module 322. A number of techniques can be employed to identify the first and second parts of the detected bit pattern. In one example, a clock signal generated by a system clock (not shown) can be scaled (down) and a window of, for example 2000 cycles (depending, of course, upon the clock speed, for example 66 MHz), can be selected and examined by analysis logic in order to identify the first and second parts of the detected bit pattern associated with the first and second step functions 502, 504, respectively. Once identification has taken place, the control and data comparison module 322 then performs a bit pattern analysis on a bit position-by-bit position basis. In this respect, the control and data comparison module 322 also retrieves a pre-stored first expected bit pattern 516, corresponding to an expectation of the first part 512 of the detected bit pattern when no fault condition occurs, and a pre-stored second expected bit pattern 518, corresponding to an expectation of the second part 514 of the detected bit pattern when no fault condition occurs. A comparison is firstly made (Step 406) between the first part 512 of the detected bit pattern and the first expected bit pattern 516. In a first example of a comparison in respect of the first step function 502, the two bit patterns are as shown in Table I below.

TABLE I

| | | | | | | |
|---|---|---|---|---|---|---|
| Detected Bits | 1 | 1 | 1 | X | 0 | 0 |
| Expected Bits | 1 | 1 | 1 | X | 0 | 0 |

In this example in respect of the first step function 502, an exact match exists between the first part 512 of the detected bit pattern and the first expected bit pattern 516. If no mismatch is found as in this example, the control and data comparison module 322 returns to analysing another step function in a pair comprising the first step function 502. However, in another example in respect of another first step function 509, the two bit patterns are as shown in Table II below.

TABLE II

| | | | | | | |
|---|---|---|---|---|---|---|
| Detected Bits | 1 | X | 0 | 0 | 0 | 0 |
| Expected Bits | 1 | 1 | 1 | X | 0 | 0 |

In this example in respect of the first step function 502, mismatches exist in respect of the fourth and fifth bit positions, a mismatch with the expected indeterminate state being ignored (bit position 3). The control and data comparison module 322, having detected a mismatch, therefore sets (Step 408) a flag (not shown) that can be used by a self-diagnostic process (also not shown) to take appropriate action (Step 410) when the display apparatus 100 is faulty and hence generate, for example, an error manage or take corrective action, for example modify the waveform generated by software, where appropriate.

Where no mismatch has been detected, the control and data comparison module 322 then proceeds to analyse the second part 514 of the detected bit pattern. The above process is thus repeated in respect of signal acquisition, translation and analysis (Steps 400, 402, 404) and a second comparison is made (Step 406) between the second part 514 of the detected bit pattern and the second expected bit pattern 518. In a first example in respect of the second step function 504, the two bit patterns are as shown in Table III below.

TABLE III

| | | | | | | |
|---|---|---|---|---|---|---|
| Detected Bits | 0 | 0 | X | 1 | 1 | 1 |
| Expected Bits | 0 | 0 | X | 1 | 1 | 1 |

In this example in respect of the second step function 504, an exact match exists between the second part 514 of the detected bit pattern and the second expected bit pattern 518. If no mismatch is found as in this example, the control and data comparison module 322 returns to analysing another pair of step functions. However, in another example in respect of another second step function 510, the second part 514 of the detected bit pattern is as shown in Table IV below.

TABLE IV

| | | | | | | |
|---|---|---|---|---|---|---|
| Detected Bits | 0 | 0 | 0 | 0 | X | 1 |
| Expected Bits | 0 | 0 | X | 1 | 1 | 1 |

In this example in respect of the second step function 504, mismatches exist in respect of the second and fourth bit positions, a mismatch between the expected indeterminate state (bit position 3) again being ignored. The control and data comparison module 322, having detected mismatches in respect of both the first step function 502 and the second step function 504, sets (Step 408) the flag (not shown) that can be used by a self-diagnostic process (also not shown) to take appropriate action when the display apparatus 100 is faulty and hence generate, for example, an error message, or take corrective action (Step 410), for example modify the waveform generated by software, where appropriate.

In another embodiment, instead of a bit position-by-bit position comparison of the first part 512 of the detected bit pattern with the first expected bit pattern 516 and a bit position-by-bit position comparison of the second part 514 of the detected bit pattern with the second expected bit pattern 518 in order to detect a fault condition, the first part 512 of the detected bit pattern and the second part 514 of the detected bit pattern, when both are identified by the waveform post-processor 232, are communicated to the control and data comparison module 322. However, the control and data comparison module 322 sums the bits of the first part 512, constituting integration, of the detected bit pattern and sums the bits of the second part 514 of the detected bit pattern. A first detected or measured value, Vd₁, is therefore generated in respect of the first part 512 of the detected bit pattern and a second detected or measured value, Vd₂, is generated in respect of the second part 514 of the detected bit pattern.

As bits are being summed, indeterminate states cannot be allowed to be generated by the signal translation module 232 in respect of signal levels falling between the first and second thresholds mentioned above. Consequently, instead of using the multi-state transformer 308 described above, a slicer is used so that either a logic 0 or a logic 1 is generated by the signal translation module 232.

In order to make comparisons, the control and data comparison module 322 also retrieves a pre-stored first expected value, Ve₁, corresponding to an expectation of the sum of the bits of the first part 512 of the detected bit pattern when no fault condition occurs, and a pre-stored second expected value, Ve₂, corresponding to an expectation of the sum of the bits of the second part 514 of the detected bit pattern when no fault condition occurs. The comparisons are then made in the same manner as described above in relation to the previous embodiment, although detected and expected values in respect of the first step function 502 and the second step function 504, respectively, are compared as opposed to respective bit position-by-bit position analyses. Consequently, if the detected and expected values associated with the first step function 502 or the detected and expected values associated with the second step function 504 do not match, then the control and data comparison module 322 sets the flag bit that can be used by the self-diagnostic process to take appropriate action when the display apparatus 100 is faulty and hence generate, for example, an error message or take corrective action. In another embodiment, a margin of error in mismatch between detected and expected values can be used in order to define an acceptable degree of match as opposed to a precise match.

In a further embodiment, instead of performing the bit position-by-bit position comparisons described above or the comparison of detected and expected values, the signal translation module 232 is capable of generating a spectrum in respect of the waveform 500, for example using a Fast Fourier Transform (FFT) module (not shown), the signal translation module 232 generating the spectrum, constituting a translated output signal representative of at least an aspect, in this example the spectrum, of the waveform 500, and communicating spectrum data to the waveform post-processor 316 of the detection module 234. The generation of the spectrum is generated in respect a number of frames of driving information (or other data structures for different applications) or a predetermined period of time, the spectrum constituting another example of translation of the waveform 500.

In order to make comparisons, the control and data comparison module 322 then retrieves a pre-stored spectrum corresponding to an expectation of the spectrum associated with the waveform 500 when no fault condition occurs. The comparison (Step 406) is then made, as in relation to the previous embodiment, between the spectrum data generated by the signal translation module 232 and the pre-stored spectrum data. Consequently, if the spectrum associated with the waveform 500 does not match the pre-stored spectrum, then the control and data comparison module 322 sets (Step 408) the flag that can be used by the self-diagnostic process to take appropriate action (Step 410) when the display apparatus 100 is faulty and hence generate, for example, an error message, or take corrective action.

Although not mentioned above, the skilled person should appreciate that the above embodiments can be used in the context of the waveform 500 relating to a static driving technique or a dynamic driving technique.

In further embodiments, compensation can be provided for factors that can lead to a false conclusion of an error condition, for example temperature drift and/or battery power drop. In this respect, a look-up table can be provided in respect of expected values and temperature and/or battery power level. Alternatively, compensation factors for the expected values can be calculated in accordance with a predetermined algorithm. In one embodiment, during manufacture, a first voltage measurement can be made in respect of a first segment and a second voltage measurement can be made in respect of a second segment. The two voltage measurements made can then be subtracted in order to generate an expected difference voltage, ΔV_{E}, between the first and second segments and stored. In such circumstances, subsequent variation in the voltage values measured during testing on account of temperature drift and/or battery power drop will result in a subsequently measured difference voltage, ΔV_{M}, remaining substantially unchanged. However, when an error occurs, the measured difference voltage, ΔV_{M}, varies beyond acceptable tolerances and so a fault condition can be detected. The above technique can, of course, be applied to other segments of the segmented display module.

The skilled person should also appreciate that although certain matching techniques have been described herein, any suitable pattern matching technique can be employed.

Furthermore, it should also be appreciated that whilst the above examples have been described in the context of a display device, the above apparatus and methods can be applied to other capacitive loads.

As mentioned above, the invention may also be implemented in a computer program for running on a computer system, at least including code portions for performing steps of a method according to the invention when run on a programmable apparatus, such as a computer system or enabling a programmable apparatus to perform functions of a device or system according to the invention. The computer program may for instance include one or more of: a subroutine, a function, a procedure, an object method, an object implementation, an executable application, an applet, a servlet, a source code, an object code, a shared library/dynamic load library and/or other sequence of instructions designed for execution on a computer system. The computer program may be provided on a data carrier, such as a CD-rom or diskette, stored with data loadable in a memory of a computer system, the data representing the computer program. The data carrier may further be a data connection, such as a telephone cable or a wireless connection.

In the foregoing specification, the invention has been described with reference to specific examples of embodiments of the invention. It will, however, be evident that various modifications and changes may be made therein without departing from the broader spirit and scope of the invention as set forth in the appended claims. For example, the connections may be an type of connection suitable to transfer signals from or to the respective nodes, units or devices, for example via intermediate devices. Accordingly, unless implied or stated otherwise the connections may for example be direct connections or indirect connections.

It is thus possible to provide a fault detection apparatus, a display system and a method of detecting a fault that improves reliability of a display device without having to modify the display device or the display driver. Improved reliability thus improves safety when the display device is used in relation to certain applications. Furthermore, it is possible to provide detection of fault conditions that can be used for faults arising from different causes, for example physical defects and software errors. Consequently, the apparatus, system and method provide increased flexibility in fault detection from a single apparatus.

Of course, the above advantages are exemplary, and these or other advantages may be achieved by the invention. Further, the skilled person will appreciate that not all advantages stated above are necessarily achieved by embodiments described herein.

The conductors as discussed herein may be illustrated or described in reference to being a single conductor, a plurality of conductors, unidirectional conductors, or bidirectional conductors. However, different embodiments may vary the implementation of the conductors. For example, separate unidirectional conductors may be used rather than bidirectional conductors and vice versa. Also, plurality of conductors may be replaced with a single conductor that transfers multiple signals serially or in a time multiplexed manner. Likewise, single conductors carrying multiple signals may be separated out into various different conductors carrying subsets of these signals. Therefore, many options exist for transferring signals.

Although the invention has been described with respect to specific conductivity types or polarity of potentials, skilled artisans appreciate that conductivity types and polarities of potentials may be reversed.

The term “program,” as used herein, is defined as a sequence of instructions designed for execution on a computer system. A program, or computer program, may include a subroutine, a function, a procedure, an object method, an object implementation, an executable application, an applet, a servlet, a source code, an object code, a shared library/dynamic load library and/or other sequence of instructions designed for execution on a computer system.

Some of the above embodiments, as applicable, may be implemented using a variety of different information processing systems. For example, although FIGS. 2 and/or 3 and the discussion thereof describe an exemplary information processing architecture, this exemplary architecture is presented merely to provide a useful reference in discussing various aspects of the invention. Of course, the description of the architecture has been simplified for purposes of discussion, and it is just one of many different types of appropriate architectures that may be used in accordance with the invention. Those skilled in the art will recognize that the boundaries between logic blocks are merely illustrative and that alternative embodiments may merge logic blocks or circuit elements or impose an alternate decomposition of functionality upon various logic blocks or circuit elements.

Thus, it is to be understood that the architectures depicted herein are merely exemplary, and that in fact many other architectures can be implemented which achieve the same functionality. In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Also for example, in one embodiment, the illustrated elements of the microcontroller 202 are circuitry located on a single integrated circuit or within a same device. Alternatively, the microcontroller 202 may include any number of separate integrated circuits or separate devices interconnected with each other. For example, display drivers 226, 228 may be located on a same integrated circuit as the fault detection apparatus 100 or on a separate integrated circuit or located within another peripheral or slave discretely separate from other elements of microcontroller 202. The segmented display module 206 may also be located on separate integrated circuits or devices. Also for example, the microcontroller 202 or portions thereof may be soft or code representations of physical circuitry or of logical representations convertible into physical circuitry. As such, the microcontroller 202 may be embodied in a hardware description language of any appropriate type.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments. Also, devices functionally forming separate devices may be integrated in a single physical device.

Also, the invention is not limited to physical devices or units implemented in non-programmable hardware but can also be applied in programmable devices or units able to perform the desired device functions by operating in accordance with suitable program code. Furthermore, the devices may be physically distributed over a number of apparatuses, while functionally operating as a single device.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

1. A fault detection apparatus comprising:
a signal translation stage having an input arranged to receive an input waveform derived, when in use, from a signal for driving a capacitive load, the signal translation stage being arranged to generate a translated output signal representative of at least an aspect of the input waveform; and
a detection stage arranged to receive the translated output signal from the signal translation stage and analyse a first part of the translated output signal corresponding to a first step function and identify first detected bits constituting the first part of the translated output signal;
wherein the analysis performed by the detection stage is a comparison of the first part of the translated output signal with an expected first part of the translated output signal.

2. An apparatus as claimed in claim 1, wherein the input waveform is an analogue signal and the signal translation stage is arranged to digitise the input waveform, the digitised input waveform constituting the translated output signal.

3. An apparatus as claimed in claim 2, wherein the translated output signal comprises a bit, the bit having a state corresponding to one of: logic 1 or logic 0.

4. An apparatus as claimed in claim 3, wherein the signal translation stage comprises a slicer.

5. An apparatus as claimed in claim 1, wherein the detection stage is arranged to sum the first detected bits to yield a first measured value.

6. An apparatus as claimed in claim 5, wherein:
a first expected value corresponds to a sum of bits of a first expected bit pattern, the first expected bit pattern constitutes the expected first part of the translated output signal; and
the comparison between the first part of the translated output signal and the expected first part of the translated output signal is a comparison of the first measured value with the first expected value.

7. An apparatus as claimed in claim 2, wherein the translated output signal comprises a bit, the bit having a state corresponding to one of: logic 1, logic 0, or an indeterminate state.

8. An apparatus as claimed in claim 7, wherein:
a first expected bit pattern constitutes the expected first part of the translated output signal;
the detection stage is arranged to identify first detected bits constituting the first part of the translated output signal; and
the detection stage is also arranged to make a bit position-by-bit position comparison of the first detected bits with the first expected bit pattern.

9. An apparatus as claimed in claim 8, wherein the first detected bits comprise a first detected bit at a first bit position and the first expected bit pattern comprises a first expected bit at a bit position corresponding to the first bit position, the detection stage being arranged to determine a mismatch between the first detected bit and the first expected bit, the mismatch being indicative of a fault condition.

10. An apparatus as claimed in claim 9, wherein the first expected bit is of a first indeterminate state, the comparison discounting any mismatch between the state of the first expected bit and a state of the first detected bit.

11. An apparatus as claimed in claim 1, wherein the signal translation stage comprises a multi-state transformer.

12. An apparatus as claimed in claim 1, wherein the signal translation stage is arranged to generate at least part of a spectrum associated with the input waveform.

13. An apparatus as claimed in claim 12, wherein the first part of the translated output signal is a first part of the spectrum associated with the first step function.

14. An apparatus as claimed in claim 1, wherein a mismatch between the first part of the translated output signal and the respective expected first part of the translated output signal is indicative of a fault condition.

15. An apparatus as claimed in claim 1, wherein the capacitive load is a segment of a display device.

16. An apparatus as claimed in claim 1, wherein the detection stage is arranged to receive the translated output signal from the signal translation stage and analyse a second part of the translated output signal corresponding to a second step function, a direction of transition of the second step function being opposite to a direction of transition of the first step function; and
the analysis performed by the detection stage includes a comparison of the second part of the translated output signal with an expected second part of the translated output signal.

17. (canceled)

18. An electronic apparatus comprising the fault detection apparatus as claimed in claim 1.

19. (canceled)

20. A method of detecting a fault for a capacitive load, the method comprising:
receiving an input waveform tapped from a signal for driving the capacitive load;
generating a translated output signal representative of at least an aspect of the input waveform;
analysing a first part of the translated output signal corresponding to a first step function and identifying first detected bits constituting the first part of the translated output signal; wherein
the analysis performed is a comparison of the first part of the translated output signal with an expected first part of the translated output signal.

21. A non-transitory computer readable storage medium comprising computer program code means to make a computer execute the method as claimed in claim 20.

22. (canceled)

23. An electronic apparatus as claimed in claim 18, further comprising:
a display device comprising a display segment; and
a display driver coupled to the display segment;
wherein the input of the signal translation stage is coupled to a tap for receiving the input waveform, the tap being coupled to the display segment and the display driver.
